(19) United States
(12) Patent Application Publication
(10) Pub. No.: US 2025/0300031 A1
(43) Pub. Date: Sep. 25, 2025

(54) PACKAGE SUBSTRATE, SEMICONDUCTOR PACKAGE INCLUDING PACKAGE SUBSTRATE AND METHOD FOR MANUFACTURING THE SAME

(71) Applicant: Samsung Electronics Co., Ltd., Suwon-si (KR)

(72) Inventor: HYUNSOO CHUNG, Suwon-si (KR)

(21) Appl. No.: 18/918,405

(22) Filed: Oct. 17, 2024

(30) Foreign Application Priority Data
Mar. 22, 2024 (KR) 10-2024-0039763

(51) Int. Cl. H01L 23/15; H01L 21/56; H01L 23/00; H01L 23/31; H01L 23/498; H01L 23/538; H01L 25/18; H10B 80/00

(52) U.S. Cl. CPC H01L 23/15; H01L 21/565; H01L 23/3128; H01L 23/49822; H01L 23/49833; H01L 23/49838; H01L 23/49894; H01L 23/5381; H01L 24/14; H01L 24/16; H01L 23/562; H01L 25/18; H01L 2224/14132; H01L 2224/16227; H01L 2224/16238; H01L 2924/1431; H01L 2924/14361; H10B 80/00

(57) ABSTRACT

A package substrate according to an embodiment may include a substrate that includes a core layer that includes a first region and a second region, a surface of the second region being recessed from a surface of the first region, and a first redistribution layer on the first region, the first redistribution layer including a first organic dielectric and a plurality of first circuit wiring lines inside the first organic dielectric, and a bridge die that is disposed on the second region and includes a connection layer that includes a glass bridge base and a plurality of wiring lines inside the glass bridge base, and a second redistribution layer on the connection layer, the second redistribution layer including an inorganic dielectric and a plurality of second circuit wiring lines inside the inorganic dielectric.

### CROSS-REFERENCE TO RELATED APPLICATION

This application claims priority to and the benefit of Korean Patent Application No. 10-2024-0039763 filed in the Korean Intellectual Property Office on Mar. 22, 2024, the entire contents of which are incorporated herein by reference.

### BACKGROUND OF THE INVENTION

### (a) Field of the Invention

The present disclosure relates to a package substrate, a semiconductor package including the package substrate, and a method for manufacturing the same.

### (b) Description of the Related Art

In order to electrically connect a semiconductor die having I/O terminals with a fine pitch to a printed circuit board (PCB) having I/O terminals with a normal pitch, an interposer having I/O terminals with an intermediate pitch between the fine pitch and the normal pitch is required. Accordingly, 2.5D semiconductor packages have been developed and used, each of which has a structure in which in order to form multiple semiconductor dies into a single package, an interposer is disposed on a printed circuit board (PCB) and multiple semiconductor dies are horizontally disposed on the interposer.

Meanwhile, with the recent development of mobile technology, semiconductor packages to be mounted in electronic products are also being developed to be smaller in order to achieve higher density and efficiency. However, since conventional 2.5D semiconductor packages have a vertical stack structure of a printed circuit board, an interposer, and semiconductor dies, they have a problem in which it is difficult to reduce their sizes in the vertical direction and power is lost on the path of the semiconductor dies through which power is transferred.

Further, in these conventional 2.5D semiconductor packages, semiconductor dies are covered by molding materials, and differences in coefficient of thermal expansion (CTE) between the individual components of the molding materials, the printed circuit boards, the interposers, and the semiconductor dies may cause warpage of the 2.5D semiconductor packages.

### SUMMARY OF THE INVENTION

The present disclosure may provide a package substrate by forming a cavity in a substrate including a glass core layer and a first buildup structure on the glass core layer and disposing a bridge die including a bridge structure including a glass bridge base and a second buildup structure on the bridge structure inside the cavity of the substrate.

An insulating layer of the first buildup structure of the substrate may be formed of an organic dielectric material, and an insulating layer of the second buildup structure of the bridge die may be formed of an inorganic dielectric material.

On a package substrate, a memory die and a logic die may be disposed, and by a single molding process, the bridge die, the memory die, and the logic die may be covered on an organic substrate by a molding material.

A package substrate according to an embodiment may include a substrate including a core layer including a first region and a second region, a surface of the second region being recessed from a surface of the first region; and a first redistribution layer on the first region, the first redistribution layer including a first organic dielectric and a plurality of first circuit wiring lines in the first organic dielectric; and a bridge die on the second region, the bridge die including: a connection layer including a glass bridge base and a plurality of wiring lines in the glass bridge base; and a second redistribution layer on the connection layer, the second redistribution layer including an inorganic dielectric and a plurality of second circuit wiring lines in the inorganic dielectric.

A semiconductor package according to an embodiment may include a substrate including a core layer including a first region and a second region, a surface of the second region being recessed from a surface of the first region; and a first redistribution layer on the first region, the first redistribution layer including a first organic dielectric and a plurality of first circuit wiring lines in the first organic dielectric; a bridge die on the second region, the bridge die including: a connection layer including a glass bridge base and a plurality of wiring lines in the glass bridge base; and a second redistribution layer on the connection layer, the second redistribution layer including an inorganic dielectric and a plurality of second circuit wiring lines in the inorganic dielectric; a first semiconductor die on the substrate and the bridge die; a second semiconductor die next to the first semiconductor die on the substrate and the bridge die; and a molding material on the substrate and covering the bridge die, the first semiconductor die, and the second semiconductor die.

A method for manufacturing a semiconductor package according to an embodiment may include providing a substrate in which a first redistribution layer is disposed on a first region and a second region of a core layer, the first region and the second region being defined by dividing a plane of the core layer, and the first redistribution layer including an organic dielectric and a plurality of first circuit wiring lines in the organic dielectric; removing a portion of the first redistribution layer that is on the second region and recessing the second region of the core layer; mounting a bridge die on the second region of the recessed core layer, the bridge die including a connection layer and a second redistribution layer on the connection layer, the connection layer including a glass bridge base and a plurality of wiring lines in the glass bridge base, and the second redistribution layer including an inorganic dielectric and a plurality of second circuit wiring lines in the inorganic dielectric; mounting a first semiconductor die and a second semiconductor die on the first redistribution layer and on the secondredistribution layer; and covering the bridge die, the first semiconductor die, and the second semiconductor die on the core layer and the first redistribution layer by a molding material.

A semiconductor package according to an embodiment may include a glass substrate; a glass bridge die in a recessed portion of the glass substrate; a first semiconductor die on the glass substrate and on the glass bridge die; and a second semiconductor die on the glass substrate and on the glass bridge die, wherein the first semiconductor die includes a plurality of first connection members and the second semiconductor die includes a plurality of second connection members, wherein the first semiconductor die is electrically connected to the second semiconductor die by wiring lines included in the glass bridge die, wherein a pitch between neighboring first connection members in a first group of the plurality of first connection members that are connected to the glass bridge die is different from a pitch between neighboring first connection members of a second group of the plurality of first connection members that are not connected to the glass bridge die, and wherein a pitch between neighboring second connection members in a first group of the plurality of second connection members that are connected to the glass bridge die is different from a pitch between neighboring second connection members of a second group of the plurality of second connection members that are not connected to the glass bridge die.

It is possible to provide a 2.5D semiconductor package by applying a package substrate including a glass substrate and a glass bridge die in a cavity of the glass substrate, without using a printed circuit board and an interposer. Accordingly, it is possible to reduce the size of the 2.5D semiconductor package by replacing a stack structure of a conventional 2.5D semiconductor package, consisting of a printed circuit board and an interposer, with the package substrate including the glass substrate and the glass bridge die.

By connecting ultrafine patterns of a memory die and a logic die through a buildup structure that is included in a bridge die and is formed of an inorganic dielectric material and connecting fine patterns of the memory die and the logic die through an upper buildup structure that is included in a substrate and is formed of an organic dielectric material, ultra-high-density connection between different types of dies is possible, and a power transfer path and a signal transfer path can be more efficiently implemented.

By manufacturing a 2.5D semiconductor package using a glass substrate and a glass bridge die having coefficients of thermal expansion (CTEs) similar to that of silicon which is the main material of a memory die and a logic die, it is possible to prevent warpage of the 2.5D semiconductor package from being caused by differences in coefficient of thermal expansion (CTE) between individual components.

By covering a glass bridge die, a memory die, and a logic die on a glass substrate by a molding material by performing a single molding process, it is possible to improve the heat dissipation characteristic of a 2.5D semiconductor package.

### BRIEF DESCRIPTION OF THE DRAWINGS

FIG. 1 is a cross-sectional view illustrating a package substrate of an embodiment.

FIG. 2 is a cross-sectional view illustrating a semiconductor package of an embodiment.

FIG. 3 is a plan view of the semiconductor package of FIG. 2 taken along line A-A′.

FIGS. 4 to 12 are cross-sectional views for explaining a method for manufacturing a semiconductor package of an embodiment.

### DETAILED DESCRIPTION OF THE EMBODIMENTS

In the following detailed description, only certain embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when an element is referred to as “on a plane”, it means that the element is viewed from above (e.g., in plan view), and when an element is referred to as “on a cross-section”, it means the element is viewed from the side in a cross-section obtained by cutting the element vertically.

Hereinafter, a package substrate 101, a semiconductor package 100 including the package substrate 101, and a method for manufacturing the same of the embodiment will be described with reference to the drawings.

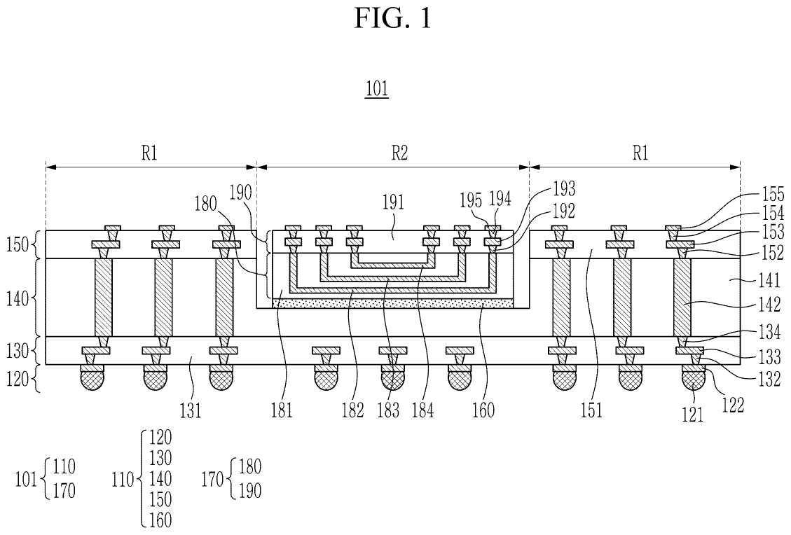

FIG. 1 is a cross-sectional view illustrating the package substrate 101 of the embodiment.

Referring to FIG. 1, the package substrate 101 includes a substrate 110 (e.g., a glass substrate) and a bridge die 170 (e.g., a glass bridge die). In a 2.5D semiconductor package, semiconductor dies may be disposed on the package substrate 101, and the package substrate 101 electrically connects the semiconductor dies to one another, and electrically connects the semiconductor dies to an external device. In the embodiment, the package substrate 101 may be manufactured based on a fan-out wafer-level packaging (FOWLP) or fan-out panel-level packaging (FOPLP) technology.

The substrate 110 includes an external connection structure 120, a lower buildup structure (e.g., a third buildup structure) 130, a core layer 140, and an upper buildup structure (e.g., a first buildup structure) 150. In the embodiment, the substrate 110 may include a glass substrate.

The external connection structure 120 is disposed on the lower surface of the lower buildup structure 130. The external connection structure 120 includes external connection members 121 and connection pads 122. The external connection members 121 electrically connect the substrate 110 to an external device (not shown in the drawings). Each of the external connection members 121 is disposed below corresponding the connection pad 122. Each of the external connection members 121 is electrically connected to the corresponding connection pad 122. Each of the connection pads 122 is disposed between a corresponding first redistribution via 132 of the lower buildup structure 130 and the corresponding external connection member 121. Each of the connection pads 122 electrically connect each of the first redistribution vias 132 of the lower buildup structure 130 to each of the external connection members 121.

The lower buildup structure 130 is disposed on the external connection structure 120. The lower buildup structure 130 includes a dielectric 131, and circuit wiring lines (e.g., third circuit wiring lines) inside the dielectric 131. In the embodiment, the lower buildup structure 130 may be a redistribution layer (RDL) structure. The circuit wiring lines (the third circuit wiring lines) include the first redistribution vias 132, first redistribution lines 133, and second redistribution vias 134.

The dielectric 131 protects and insulates the first redistribution vias 132, the first redistribution lines 133, and the second redistribution vias 134. On the upper surface of the dielectric 131, the core layer 140 is disposed. On the lower surface of the dielectric 131, the external connection structure 120 is disposed. In the embodiment, the dielectric 131 may include an organic dielectric material (e.g., a second organic dielectric material). In the embodiment, the dielectric 131 may include a photoimageable dielectric (PID) that is used in a redistribution process. The photoimageable dielectric (PID) is a material applicable to a photolithography process to form fine patterns. As an embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer.

Each of the first redistribution vias 132 is disposed between a corresponding first redistribution line 133 and a corresponding connection pad 122. Each of the first redistribution vias 132 electrically connects the corresponding first redistribution line 133 to the corresponding connection pad 122 in the vertical direction. Each of the first redistribution lines 133 is disposed between the corresponding first redistribution via 132 and a corresponding second redistribution via 134. Each of the first redistribution lines 133 electrically connects the corresponding first redistribution via 132 to the corresponding second redistribution via 134 in the horizontal direction. Each of the second redistribution vias 134 is disposed between the corresponding first redistribution line 133 and a corresponding through-core via 142.

Each of the second redistribution vias 134 electrically connects the corresponding through-core via 142 to the corresponding first redistribution line 133. In the embodiment, the first redistribution vias 132, the first redistribution lines 133, and the second redistribution vias 134 may include at least one of copper, aluminum, tungsten, nickel, gold, tin, titanium, and alloys thereof, respectively. In other embodiments, the lower buildup structure 130 may include fewer or more redistribution lines and redistribution vias, which is also included in the scope of the present disclosure.

The core layer 140 is disposed on the lower buildup structure 130. The core layer 140 includes a core 141 and the through-core vias 142. In the embodiment, the core 141 may include a glass core. In the embodiment, the glass core may include borosilicate glass, quartz, or alkali-free glass. The core layer 140 includes a first region R1, and a second region R2 recessed from the first region R1. For example, a surface (e.g., a top surface) of the second region R2 may be recessed from a surface (e.g., a top surface) of the first region R1. The first region R1 and the second region R2 are defined by dividing the plane of the core layer 140. For example, the first region R1 and the second region R2 may be next to each other in the horizontal direction. For example, the first region R1 may surround the second region R2 in the horizontal direction. On the first region R1, the upper buildup structure 150 is disposed. On the second region R2, the bridge die 170 is disposed.

The through-core vias 142 are positioned in the core 141. In the embodiment, the through-core vias 142 may be through-glass vias (TGVs). In the embodiment, the through-core vias 142 may be formed by performing laser processing or mechanical processing on the core 141. In the embodiment, the through-core vias 142 may be formed by completely filling the insides of via holes passing through the core 141 with a conductive material. In the embodiment, the through-core vias 142 may be formed by conformally forming a conductive material along the inner walls of the via holes and filling the remaining spaces in the via holes with a dielectric material. In the embodiment, the conductive material inside the through-core vias 142 may include at least one of copper, aluminum, tungsten, nickel, gold, tin, titanium, and alloys thereof. In the embodiment, the dielectric material inside the through-core vias 142 may include photoimageable dielectric (PID), glass fiber injected with a synthetic resin, such as a woven glass mat (glass-epoxy) impregnated with epoxy, polyimide, FR-4, resin cyanate ester, Teflon (PTFE), polyethylene ether, and a mixture thereof.

The upper buildup structure 150 is disposed on the core layer 140. The upper buildup structure 150 is disposed on the first region R1 of the core layer 140. The upper buildup structure 150 includes a dielectric 151, circuit wiring lines (e.g., first circuit wiring lines) inside the dielectric 151, and first bonding pads 155 on the dielectric 151. In the embodiment, the upper buildup structure 150 may be a redistribution layer (RDL) structure. The circuit wiring lines (the first circuit wiring lines) include third redistribution vias 152, second redistribution lines 153, and fourth redistribution vias 154.

The dielectric 151 protects and insulates the third redistribution vias 152, the second redistribution lines 153, and the fourth redistribution vias 154. On the lower surface of the dielectric 151, the core layer 140 is disposed. In the embodiment, the dielectric 151 may include an organic dielectric material (e.g., a first organic dielectric material). In the embodiment, the dielectric 151 may include a photoimageable dielectric (PID) that is used in a redistribution process.

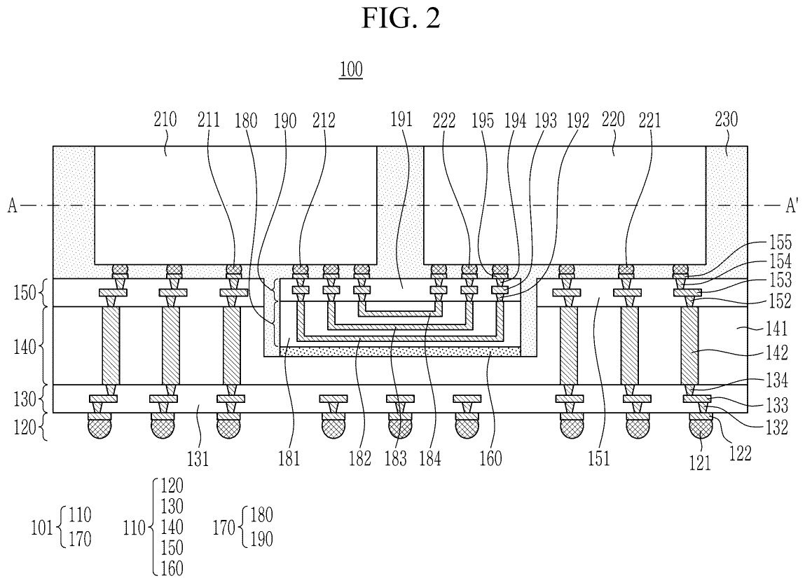

Each of the third redistribution vias 152 is disposed between a corresponding through-core via 142 and a corresponding second redistribution line 153. Each of the third redistribution vias 152 electrically connects the corresponding second redistribution line 153 to the corresponding through-core via 142 in the vertical direction. Each of the second redistribution lines 153 is disposed between the corresponding third redistribution via 152 and a corresponding fourth redistribution via 154. Each of the second redistribution lines 153 electrically connects the corresponding third redistribution via 152 to the corresponding fourth redistribution via 154 in the horizontal direction. Each of the fourth redistribution vias 154 is disposed between the corresponding second redistribution line 153 and a corresponding first bonding pad 155. Each of the fourth redistribution vias 154 electrically connects the corresponding first bonding pad 155 to the corresponding second redistribution line 153. Each of the first bonding pads 155 is disposed between the corresponding fourth redistribution via 154 and a corresponding first connection member 211 (see, e.g., FIG. 2) or between the corresponding fourth redistribution via 154 and a corresponding third connection member 221 (see, e.g., FIG. 2). Each of the first bonding pads 155 electrically connects the corresponding first connection member 211 to the corresponding fourth redistribution via 154 or the corresponding third connection member 221 to the corresponding fourth redistribution via 154.

In the embodiment, the third redistribution vias 152, the second redistribution lines 153, the fourth redistribution vias 154, and the first bonding pads 155 may include at least one of copper, aluminum, tungsten, nickel, gold, tin, titanium, and alloys thereof, respectively. In other embodiments, the upper buildup structure 150 may include fewer or more redistribution lines, redistribution vias, and first bonding pads, which is also included in the scope of the present disclosure.

An adhesive member 160 is disposed between the bridge die 170 and the second region R2 of the core layer 140 of the substrate 110. The adhesive member 160 attaches the bridge die 170 to the second region R2 of the core layer 140 of the substrate 110. In the embodiment, the adhesive member 160 may include die attach film (DAF). In the embodiment, the adhesive member 160 may include adhesive tape, Ag paste, an epoxy resin, or polyimide. In the embodiment, the adhesive member 160 may include a thermal interface material (TIM). In an embodiment, the thermal interface material (TIMs) may include thermal paste, thermal pads, a phase change material (PCM), or a metallic material. In an embodiment, the thermal interface material (TIMs) may include grease.

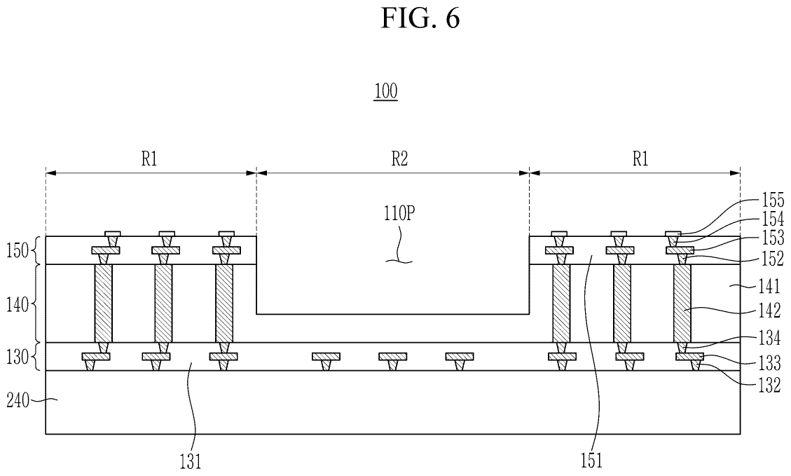

The bridge die 170 is disposed on the second region R2 of the core layer 140. The bridge die 170 is disposed inside a cavity 110P (see, e.g., FIG. 6) of the core layer 140. The bridge die 170 includes a bridge structure 180 (e.g., a connection layer) and a buildup structure (e.g., a second buildup structure or second redistribution layer) 190. The bridge die 170 electrically connects a first semiconductor die 210 to a second semiconductor die 220 in the horizontal direction (see, e.g., FIG. 2). In the embodiment, the bridge die 170 may include a glass bridge die. The bridge die 170 may be formed with or without logic circuitry. For example, the bridge die 170 may be formed to include wiring lines that connect the first semiconductor die 210 to the second semiconductor die 220 without including any circuitry that performs a logic operation on one or more signals transmitted between the first semiconductor die 210 and the second semiconductor die 220.

The bridge structure 180 includes a bridge base 181, first wiring lines 182, second wiring lines 183, and third wiring lines 184. The bridge base 181 protects and insulates the first wiring lines 182, the second wiring lines 183, and the third wiring lines 184. In the embodiment, the bridge base 181 may be a glass bridge base. In the embodiment, the bridge base 181 may include borosilicate glass, quartz, or alkali-free glass.

The first wiring lines 182, the second wiring lines 183, and the third wiring lines 184 electrically connect the first semiconductor die 210 to the second semiconductor die 220, and quickly transfer signals of the first semiconductor die 210 to the second semiconductor die 220 in the horizontal direction. In the embodiment, the first wiring lines 182, the second wiring lines 183, and the third wiring lines 184 may include at least one of copper, aluminum, tungsten, nickel, gold, tin, titanium, and alloys thereof, respectively. In other embodiments, the bridge structure 180 may include fewer or more wiring lines, which is also included in the scope of the present disclosure.

The buildup structure 190 is disposed on the bridge structure 180. The buildup structure 190 includes a dielectric 191, circuit wiring lines (e.g., second circuit wiring lines) inside the dielectric 191, and second bonding pads 195 on the dielectric 191. The circuit wiring lines (the second circuit wiring lines) include first vias 192, first lines 193, and second vias 194.

The dielectric 191 protects and insulates the first vias 192, the first lines 193, and the second vias 194. On the lower surface of the dielectric 191, the bridge structure 180 is disposed. In the embodiment, the dielectric 191 may include an inorganic dielectric material. In the embodiment, the dielectric 191 may include at least one of silicon oxide and silicon nitride.

Each of the first vias 192 is disposed between a corresponding first wiring line 182 and a corresponding first line 193, between a corresponding second wiring lines 183 and the corresponding first line 193, and between a corresponding third wiring lines 184 and the corresponding first line 193. Each of the first vias 192 electrically connects the corresponding first line 193 to the corresponding first wiring line 182, the corresponding first lines 193 to the corresponding second wiring line 183, and the corresponding first line 193 to the corresponding third wiring line 184. Each of the first lines 193 is disposed between the corresponding first via 192 and a corresponding second via 194. Each of the first lines 193 electrically connects the corresponding first via 192 to the corresponding second via 194 in the horizontal direction. Each of the second vias 194 is disposed between the corresponding first line 193 and a corresponding second bonding pad 195. Each of the second vias 194 electrically connects the corresponding second bonding pad 195 to the corresponding first line 193. Each of the second bonding pads 195 is disposed between the corresponding second via 194 and a corresponding second connection member 212 (see FIG. 2) or between the corresponding second via 194 and a corresponding fourth connection member 222 (see FIG. 2). Each of the second bonding pads 195 electrically connects the corresponding second connection member 212 to the corresponding second via 194, or the corresponding fourth connection member 222 to the corresponding second via 194.

In the embodiment, the first vias 192, the first lines 193, the second vias 194, and the second bonding pads 195 may include at least one of copper, aluminum, tungsten, nickel, gold, tin, titanium, and alloys thereof, respectively. In other embodiments, the buildup structure 190 may include fewer or more lines, vias, and second bonding pads, which is also included in the scope of the present disclosure.

According to the present disclosure, it is possible to provide the package substrate 101, which includes the substrate 110 that includes the core layer 140 formed of a glass material, and the bridge die 170 that is disposed inside the cavity formed in the substrate 110 and is formed of a glass material. This glass material has a surface roughness of 10 nm or less. Therefore, by manufacturing the substrate 110 and the bridge die 170 using the glass material, it is possible to reduce changes in the positions of components that are formed on the substrate 110 and the bridge die 170. Further, the glass material has a coefficient of thermal expansion (CTE) similar to the coefficient of thermal expansion of silicon which is the main material of semiconductor dies. Therefore, by manufacturing the substrate 110 and the bridge die 170 using glass cores, it is possible to reduce warpage of the 2.5D semiconductor package due to differences in coefficient of thermal expansion (CTE) between individual components.

According to the present disclosure, it is possible to provide the package substrate 101, wherein the dielectric 151 of the upper buildup structure 150 of the substrate 110 is formed of the organic dielectric material, and the dielectric 191 of the buildup structure 190 of the bridge die 170 is formed of the inorganic dielectric material. The organic dielectric material is a material capable of forming fine patterns, and the inorganic dielectric material is a material capable of forming ultrafine patterns. The manufacturing cost of the buildup structure formed using the organic dielectric material is lower than the manufacturing cost of the buildup structure formed using the inorganic dielectric material. In this manner, in view of the pitches between patterns, the manufacturing cost, and the like, power lines and ground lines that are formed as fine patterns of a memory die and a logic die may be routed through the upper buildup structure 150 of the substrate 110 that is formed of the organic dielectric material, and signal lines that are formed as ultrafine patterns of the memory die and the logic die may be connected to each other through the buildup structure 190 of the bridge die 170 that is formed of the inorganic dielectric material. Accordingly, ultra-high-density connection between different types of dies is possible, and the manufacturing cost may be reduced, and a power transfer path and a signal transfer path can be more efficiently implemented.

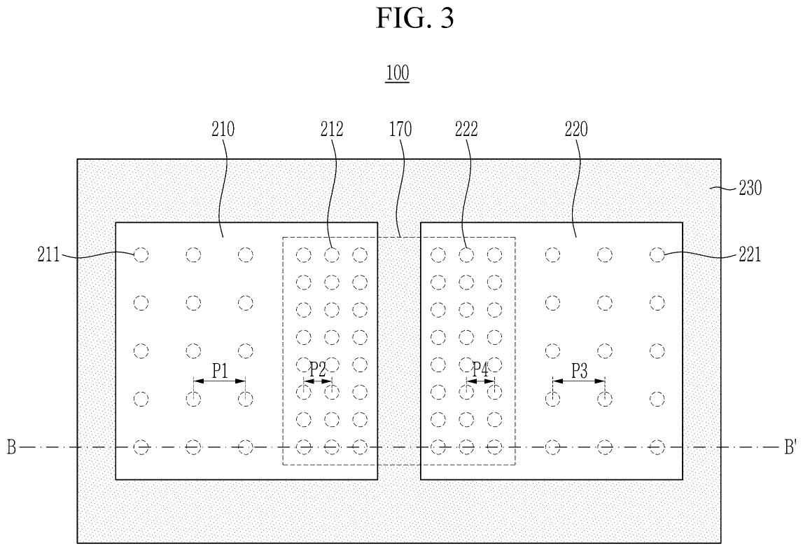

FIG. 2 is a cross-sectional view illustrating the semiconductor package 100 according to the embodiment. FIG. 2 is a cross-sectional view of the semiconductor package 100 of FIG. 3, taken along line B-B′.

Referring to FIG. 2, the semiconductor package 100 includes the package substrate 101, the first semiconductor die 210, the first connection members 211, the second connection members 212, the second semiconductor die 220, the third connection members 221, the fourth connection members 222, and a molding material 230. In an embodiment, the semiconductor package 100 may be manufactured based on a fan-out wafer-level packaging (FOWLP) or fan-out panel-level packaging (FOPLP) technology.

The first semiconductor die 210 is disposed on the package substrate 101. The first semiconductor die 210 is disposed on the substrate 110 and the bridge die 170. For example, a portion of the first semiconductor die 210 may be disposed on the substrate 110 and another portion of the first semiconductor die 210 may be disposed on the bridge die 170. The first semiconductor die 210 is disposed side by side with the second semiconductor die 220. The first semiconductor die 210 is disposed next to the second semiconductor die 220. For example, a portion of the second semiconductor die 220 may be disposed on the substrate 110 and another portion of the second semiconductor die 220 may be disposed on the bridge die 170. In the embodiment, the first semiconductor die 210 may include a logic die. In the embodiment, the first semiconductor die 210 may include an application processor (AP). In the embodiment, the first semiconductor die 210 may include at least one of central processing units (CPUs) and graphic processing units (GPUs).

The first connection members 211 are disposed between the upper buildup structure 150 of the substrate 110 and the first semiconductor die 210.

The first connection members 211 electrically connect the first semiconductor die 210 to the upper buildup structure 150 of the substrate 110. The second connection members 212 are disposed between the buildup structure 190 of the bridge die 170 and the first semiconductor die 210. The second connection members 212 electrically connect the first semiconductor die 210 to the buildup structure 190 of the bridge die 170.

The second semiconductor die 220 is disposed on the package substrate 101. The second semiconductor die 220 is disposed on the substrate 110 and the bridge die 170. The second semiconductor die 220 is disposed side by side with the first semiconductor die 210. The second semiconductor die 220 is disposed next to the first semiconductor die 210. In the embodiment, the second semiconductor die 220 may include a memory die. In the embodiment, the second semiconductor die 220 may be a high bandwidth memory (HBM).

The third connection members 221 are disposed between the upper buildup structure 150 of the substrate 110 and the second semiconductor die 220. The third connection members 221 electrically connect the second semiconductor die 220 to the upper buildup structure 150 of the substrate 110. The fourth connection members 222 are disposed between the buildup structure 190 of the bridge die 170 and the second semiconductor die 220. The fourth connection members 222 electrically connect the second semiconductor die 220 to the buildup structure 190 of the bridge die 170.

The first semiconductor die 210 is disposed on the upper buildup structure 150 of the substrate 110 and on the buildup structure 190 of the bridge die 170. The second semiconductor die 220 is disposed on the upper buildup structure 150 of the substrate 110 and on the buildup structure 190 of the bridge die 170. The upper buildup structure 150 has a first surface that is in contact with the core layer 140 and a second surface that is the opposite surface to the first surface, and the buildup structure 190 has a third surface that is in contact with the bridge structure 180 and a fourth surface that is the opposite surface to the third surface. Since the first semiconductor die 210 and the second semiconductor die 220 are disposed on the upper buildup structure 150 and the buildup structure 190, the second surface of the upper buildup structure 150 is formed at the same vertical level as the fourth surface of the buildup structure 190.

The molding material 230 is disposed on the upper buildup structure 150 of the substrate 110 and on the second region R2 of the core layer 140. The molding material 230 covers the adhesive member 160, the bridge die 170, the first semiconductor die 210, the second semiconductor die 220, and the first to fourth connection members 211, 212, 221, and 222.

According to the present disclosure, without using printed circuit boards and interposers for conventional 2.5D semiconductor packages, it is possible to provide a 2.5D semiconductor package adopting the package substrate 101 which includes the substrate 110 that is formed of the glass material and the bridge die 170 that is disposed inside the cavity of the substrate 110 and is formed of the glass material. Accordingly, it is possible to reduce the size of the 2.5D semiconductor package by replacing a stack structure of a conventional 2.5D semiconductor package, consisting of a printed circuit board and an interposer, with the package substrate 101.

FIG. 3 is a plan view of the semiconductor package 100 of FIG. 2, taken along line A-A′. In FIG. 3, since the bridge die 170 and the first to fourth connection members 211, 212, 221, and 222 are positioned below line A-A′, the bridge die 170 and the first to fourth connection members 211, 212, 221, and 222 are shown by dashed lines.

Referring to FIG. 3, the first semiconductor die 210 and the second semiconductor die 220 are disposed side by side. The first semiconductor die 210 is electrically connected to the substrate 110 through the first connection members 211. The second semiconductor die 220 is electrically connected to the substrate 110 through the third connection members 221. The first semiconductor die 210 is electrically connected to the bridge die 170 through the second connection members 212 disposed on a lower surface of the first semiconductor die 210. The second semiconductor die 220 is electrically connected to the bridge die 170 through the fourth connection members 222 disposed on a lower surface of the second semiconductor die 220. The bridge die 170 electrically connects the first semiconductor die 210 and the second semiconductor die 220 through the second connection members 212 and the fourth connection members 222, respectively.

The wiring lines that are formed as fine patterns inside the first semiconductor die 210 and the second semiconductor die 220 are routed through the first connection members 211 and the third connection members 221. The wiring lines that are formed as ultrafine patterns inside the first semiconductor die 210 and the second semiconductor die 220 are connected to each other through the second connection members 212 and the fourth connection members 222.

Neighboring first connection members 211 among the first connection members 211 have a first pitch P1 in the horizontal direction. Neighboring second connection members 212 among the second connection members 212 have a second pitch P2 in the horizontal direction. The first pitch P1 is larger than the second pitch P2. Neighboring third connection members 221 among the third connection members 221 have a third pitch P3 in the horizontal direction. Neighboring fourth connection members 222 among the fourth connection members 222 have a fourth pitch P4 in the horizontal direction. The third pitch P3 is larger than the fourth pitch P4.

For example, the pitch between neighboring first connection members 211 in a first group of the plurality of first connection members 211 that are connected to the bridge die 170 is smaller than the pitch between neighboring first connection members 212 of a second group of the plurality of first connection members 212 that are not connected to the glass bridge die 170. For example, the pitch between neighboring second connection members 221 in a first group of the plurality of second connection members 221 that are connected to the bridge die 170 is smaller than the pitch between neighboring second connection members 222 of the second group of the plurality of second connection members 222 that are not connected to the bridge die 170.

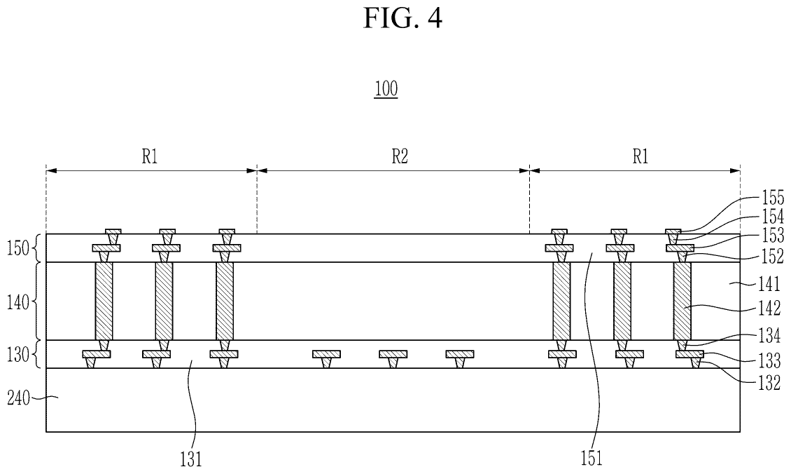

FIGS. 4 to 12 are cross-sectional views for explaining a method for manufacturing the semiconductor package 100 of the embodiment.

FIG. 4 is a cross-sectional view illustrating a step of providing the substrate 110.

Referring to FIG. 4, the lower buildup structure 130 is provided on a carrier 240. In the embodiment, the carrier 240 may include a silicon-based material such as glass or silicon oxide, an organic material, or other materials such as aluminum oxide, any combination of these materials, etc. The core layer 140 is provided on the lower buildup structure 130 and the upper buildup structure 150 is provided on the core layer 140. The upper buildup structure 150 is disposed on the first region R1 and second region R2 of the core layer 140.

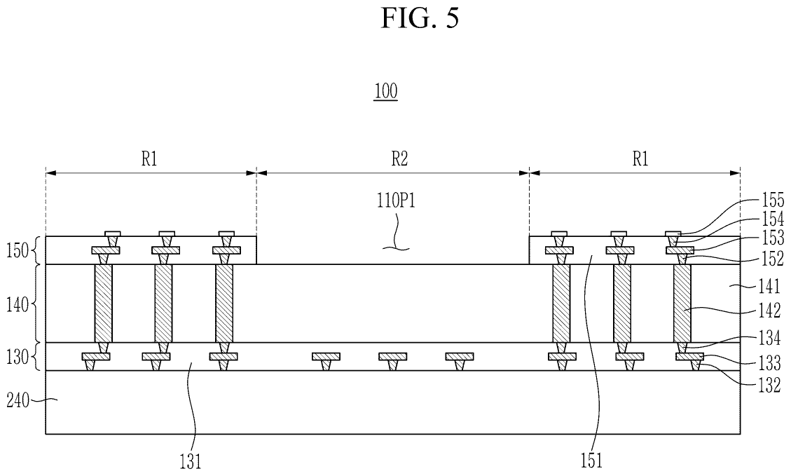

FIG. 5 is a cross-sectional view illustrating a step of removing the upper buildup structure 150 on the second region R2 of the core layer 140 of the substrate 110.

Referring to FIG. 5, the upper buildup structure 150 on the second region R2 of the core layer 140 of the substrate 110 is removed such that a through-opening 110P1 of the upper buildup structure 150 is formed. In the embodiment, the through-opening 110P1 of the upper buildup structure 150 may be formed through a step of depositing a photoresist (not shown in the drawings) on the upper buildup structure 150 of the first region R1 and second region R2 of the core layer 140 of the substrate 110, selectively exposing and developing the photoresist to form a photoresist pattern (not shown in the drawings) including a hole, and performing an etching process using the photoresist pattern as an etch mask.

FIG. 6 is a cross-sectional view illustrating a step of removing a portion of the core layer 140 in the second region R2.

Referring to FIG. 6, the cavity 110P of the substrate 110 is formed by recessing the core layer 140 of the second region R2. In the embodiment, the cavity 110P of the substrate 110 may be formed by performing laser processing or mechanical processing on the core 141. In the embodiment, the cavity 110P of the substrate 110 may be formed through a step of performing exposure, developing, and etching processes.

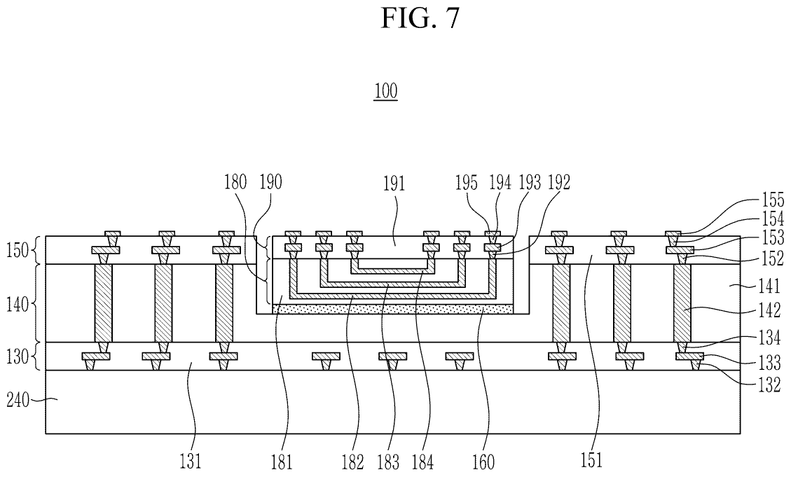

FIG. 7 is a cross-sectional view illustrating a step of attaching the bridge die 170 onto the second region R2 of the recessed core layer 140.

Referring to FIG. 7, the bridge die 170 is attached onto the second region R2 of the recessed core layer 140. The bridge die 170 is disposed inside the cavity 110P of the substrate 110. The bridge die 170 is attached onto the second region R2 of the core layer 140 recessed by the adhesive member 160 to form the package substrate 101. The bridge base 181 of the bridge structure 180 of the bridge die 170 and the core 141 of the core layer 140 may include the same glass material.

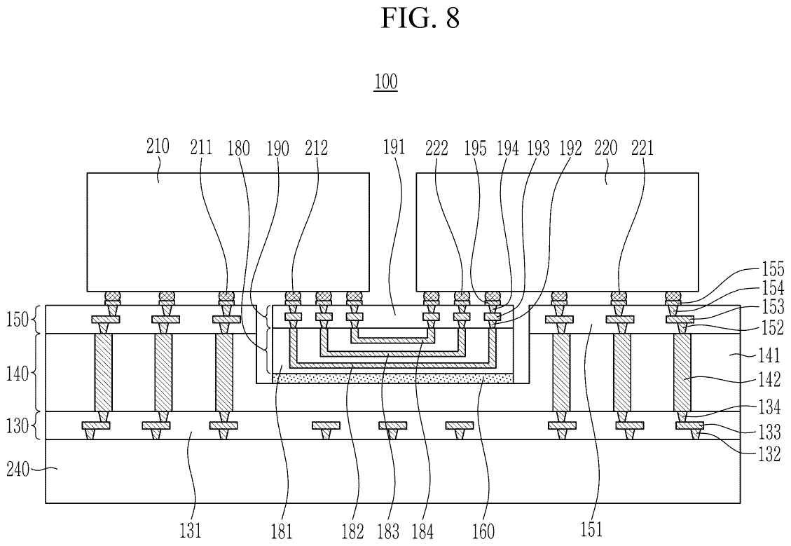

FIG. 8 is a cross-sectional view illustrating a step of mounting the first semiconductor die 210 and the second semiconductor die 220 on the package substrate 101.

Referring to FIG. 8, the first semiconductor die 210 and the second semiconductor die 220 are mounted on the package substrate 101. The first semiconductor die 210 and the second semiconductor die 220 are mounted on the upper buildup structure 150 of the substrate 110 and on the buildup structure 190 of the bridge die 170. The first semiconductor die 210 and the second semiconductor die 220 are mounted by flip-chip bonding. The first semiconductor die 210 is bonded to the upper buildup structure 150 of the substrate 110 through the first connection members 211 such that the first semiconductor die 210 and the substrate 110 are electrically connected to each other. The first semiconductor die 210 is bonded to the buildup structure 190 of the bridge die 170 through the second connection members 212 such that the first semiconductor die 210 and the bridge die 170 are electrically connected to each other. The second semiconductor die 220 is bonded to the upper buildup structure 150 of the substrate 110 through the third connection members 221 such that the second semiconductor die 220 and the substrate 110 are electrically connected to each other. The second semiconductor die 220 is bonded to the buildup structure 190 of the bridge die 170 through the fourth connection members 222 such that the second semiconductor die 220 and the bridge die 170 are electrically connected to each other. In the embodiment, the first connection members 211, the second connection members 212, the third connection members 221, and the fourth connection members 222 may include micro bumps or solder balls. In the embodiment, the first connection members 211, the second connection members 212, the third connection members 221, and the fourth connection members 222 may include at least one of tin, silver, lead, nickel, copper, or alloys thereof, respectively.

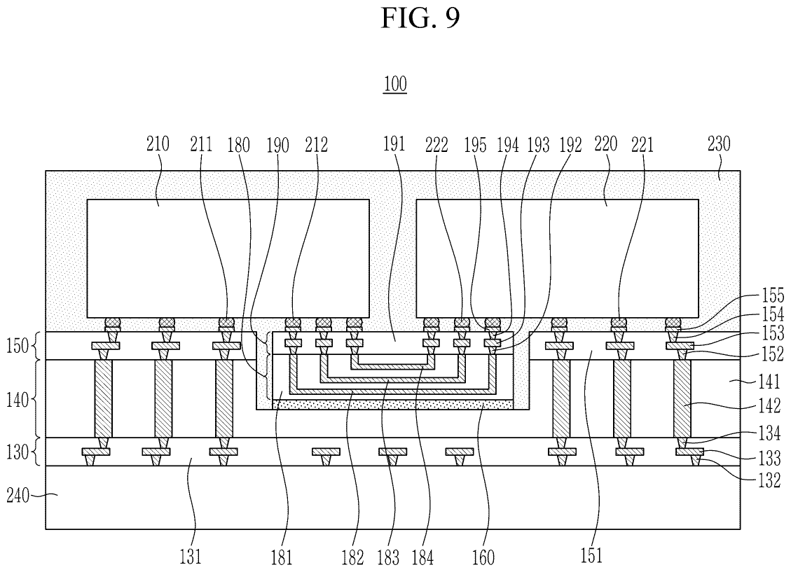

FIG. 9 is a cross-sectional view illustrating a step of covering the adhesive member 160, the bridge die 170, the first semiconductor die 210, and the second semiconductor die 220 on the second region R2 of the recessed core layer 140 and the upper buildup structure 150 by the molding material 230.

Referring to FIG. 9, by performing a single molding process, the adhesive member 160, the bridge die 170, the first semiconductor die 210, and the second semiconductor die 220 are covered on both the second region R2 of the recessed core layer 140 and the upper buildup structure 150 by the molding material 230. In the embodiment, the process of performing encapsulating by the molding material 230 may include a compression molding or transfer molding process. In the embodiment, the molding material 230 may include an epoxy molding compound (EMC).

The same molding material 230 may be continuously provided in the recessed portion of the core 141 surrounding the bridge die 170, on the upper buildup structure 150, on the first semiconductor die 210, on the second semiconductor die 220, and surrounding the connection members 211, 212, 221, and 222. For example, the molding material 230 may be formed using a single process.

According to the present disclosure, by covering the adhesive member 160, the bridge die 170, the first semiconductor die 210, and the second semiconductor die 220, disposed at different levels, on the substrate 110 by one molding material by performing a single molding process, it is possible to improve the heat dissipation characteristic of the 2.5D semiconductor package.

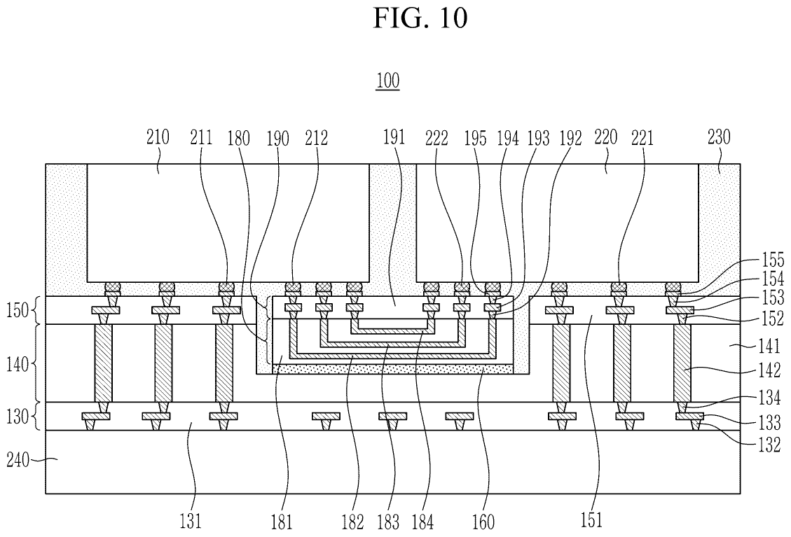

FIG. 10 is a cross-sectional view illustrating a step of planarizing the molding material 230.

Referring to FIG. 10, in order to level the upper surface of the molding material 230, chemical mechanical polishing (CMP) is performed. By applying the CMP process, the upper surface of the molding material 230 is planarized. After the CMP process is performed, the upper surface of the first semiconductor die 210 and the upper surface of the second semiconductor die 220 are exposed from the molding material 230.

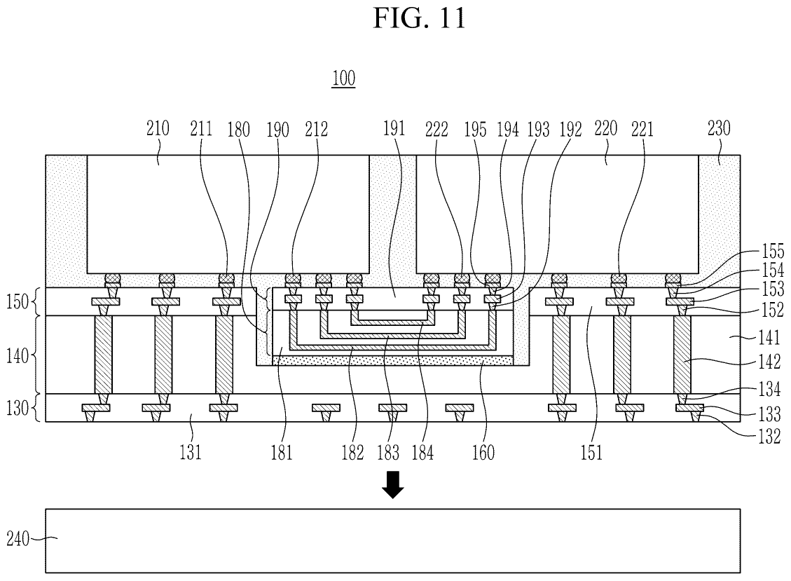

FIG. 11 is a cross-sectional view illustrating a step of removing the carrier 240 from the substrate 110.

Referring to FIG. 11, the carrier 240 is removed from the substrate 110.

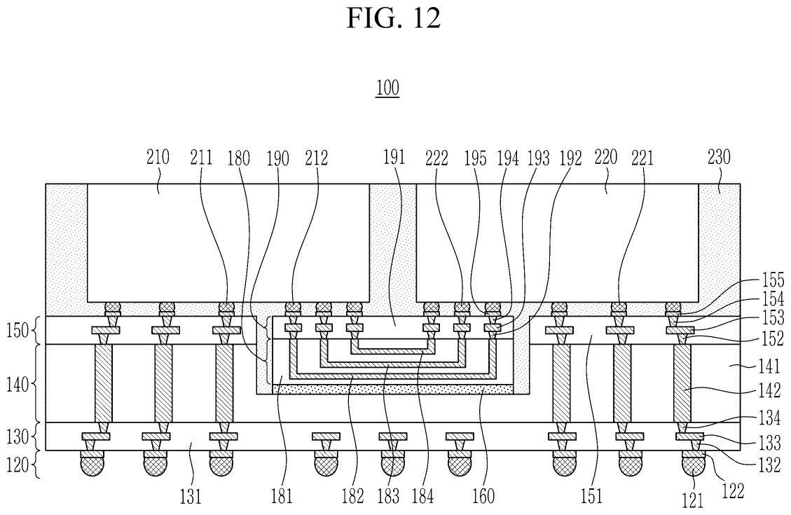

FIG. 12 is a cross-sectional view illustrating a step of forming the external connection structure 120 on the lower surface of the substrate 110.

Referring to FIG. 12, the connection pads 122 are formed on the lower surface of the substrate 110. In the embodiment, the connection pads 122 may be formed by performing a sputtering process, or by forming a seed metal layer and then performing an electroplating process. In the embodiment, the connection pads 122 may include at least one of copper, aluminum, tungsten, nickel, gold, tin, titanium, and alloys thereof. On the connection pads 122, the external connection members 121 are formed. In the embodiment, the external connection members 121 may include bumps or solder balls. In the embodiment, the external connection members 121 may include at least one of tin, silver, lead, nickel, copper, or alloys thereof. In other embodiments, the external connection structure 120 may include fewer or more connection pads and external connection members, which is also included in the scope of the present disclosure.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A package substrate comprising:
a substrate including:
a core layer including a first region and a second region, a surface of the second region being recessed from a surface of the first region; and
a first redistribution layer on the first region, the first redistribution layer including a first organic dielectric and a plurality of first circuit wiring lines in the first organic dielectric; and
a bridge die on the second region, the bridge die including:
a connection layer including a glass bridge base and a plurality of wiring lines in the glass bridge base; and
a second redistribution layer on the connection layer, the second redistribution layer including an inorganic dielectric and a plurality of second circuit wiring lines in the inorganic dielectric.

2. The package substrate of claim 1, wherein:
the substrate is formed of glass.

3. The package substrate of claim 1, wherein:
the core layer includes a core and a plurality of through-core vias.

4. The package substrate of claim 3, wherein:
the core is formed of glass.

5. The package substrate of claim 4, wherein:
the plurality of through-core vias includes through-glass vias.

6. The package substrate of claim 1, wherein:
the first organic dielectric includes a photoimageable dielectric (PID).

7. The package substrate of claim 1, wherein:
the inorganic dielectric includes at least one of silicon oxide and silicon nitride.

8. The package substrate of claim 1, wherein:
the first redistribution layer includes a first surface in contact with the core layer, and a second surface opposite to the first surface,
the second redistribution layer includes a third surface in contact with the connection layer, and a fourth surface opposite to the third surface, and
a vertical level of the second surface of the first redistribution layer is the same as a vertical level of the fourth surface of the second redistribution layer.

9. The package substrate of claim 1, further comprising:
a third redistribution layer,
wherein the core layer is interposed between the first redistribution layer and the third redistribution layer and between the bridge die and the third redistribution layer.

10. The package substrate of claim 9, wherein:
the third redistribution layer includes a second organic dielectric and third circuit wiring lines in the second organic dielectric, and
the second organic dielectric includes a photoimageable dielectric (PID).

11. The package substrate of claim 1, further comprising:
an adhesive member between the bridge die and the core layer.

12. A semiconductor package comprising:
a substrate including:
a core layer including a first region and a second region, a surface of the second region being recessed from a surface of the first region; and
a first redistribution layer on the first region, the first redistribution layer including a first organic dielectric and a plurality of first circuit wiring lines in the first organic dielectric;
a bridge die on the second region, the bridge die including:
a connection layer including a glass bridge base and a plurality of wiring lines in the glass bridge base; and
a second redistribution layer on the connection layer, the second redistribution layer including an inorganic dielectric and a plurality of second circuit wiring lines in the inorganic dielectric;
a first semiconductor die on the substrate and the bridge die;
a second semiconductor die next to the first semiconductor die on the substrate and the bridge die; and
a molding material on the substrate and covering the bridge die, the first semiconductor die, and the second semiconductor die.

13. The semiconductor package of claim 12, further comprising:
a plurality of first connection members between the first semiconductor die and the first redistribution layer;
a plurality of second connection members between the first semiconductor die and the second redistribution layer;
a plurality of third connection members between the second semiconductor die and the first redistribution layer; and
a plurality of fourth connection members between the second semiconductor die and the second redistribution layer.

14. The semiconductor package of claim 13, wherein:
neighboring first connection members among the plurality of first connection members have a first pitch in a horizontal direction,
neighboring second connection members among the plurality of second connection members have a second pitch in the horizontal direction,
the first pitch is larger than the second pitch,
neighboring third connection members among the plurality of third connection members have a third pitch in the horizontal direction,
neighboring fourth connection members among the plurality of fourth connection members have a fourth pitch in the horizontal direction, and
the third pitch is larger than the fourth pitch.

15. The semiconductor package of claim 12, wherein:
the molding material includes a molded underfill (MUF).

16. The semiconductor package of claim 12, wherein:
the bridge die electrically connects the first semiconductor die to the second semiconductor die.

17. The semiconductor package of claim 12, wherein:
the first semiconductor die includes a logic die.

18. The semiconductor package of claim 12, wherein:
the first semiconductor die includes a high bandwidth memory (HBM).

19. A method for manufacturing a semiconductor package, the method comprising:
providing a substrate in which a first redistribution layer is disposed on a first region and a second region of a core layer, the first region and the second region being defined by dividing a plane of the core layer, and the first redistribution layer including an organic dielectric and a plurality of first circuit wiring lines in the organic dielectric;
removing a portion of the first redistribution layer that is on the second region and recessing the second region of the core layer;
mounting a bridge die on the second region of the recessed core layer, the bridge die including a connection layer and a second redistribution layer on the connection layer, the connection layer including a glass bridge base and a plurality of wiring lines in the glass bridge base, and the second redistribution layer including an inorganic dielectric and a plurality of second circuit wiring lines in the inorganic dielectric;
mounting a first semiconductor die and a second semiconductor die on the first redistribution layer and on the second redistribution layer; and
covering the bridge die, the first semiconductor die, and the second semiconductor die on the core layer and the first redistribution layer by a molding material.

20. The method for manufacturing the semiconductor package according to claim 19, wherein:
in the step of covering by the molding material, the bridge die, the first semiconductor die, and the second semiconductor die are covered by the molding material by a single process.
